(19) United States
(12) Patent Application Publication
(10) Pub. No.: US 2002/0047131 A1
(43) Pub. Date: Apr. 25, 2002

(54) Selective placement of quantum wells in flipchip light emitting diodes for improved light extraction

(76) Inventors: Michael J. Ludowise, San Jose, CA (US); Yu-Chen Shen, San Jose, CA (US); Michael R. Krames, Mountain View, CA (US)

Correspondence Address: George Wolken Jr., SKJERVEN MORRILL MacPHERSON LLP, Suite 700, 25 Metro Drive, San Jose, CA, 95110-1349, US

(21) Appl. No.: 09/977,144

(22) Filed: Oct. 11, 2001

Related U.S. Application Data
(63) Continuation-in-part of application No. 09/469,657, filed on Dec. 22, 1999.

(51) Int. Cl. H01L 33/00

(52) U.S. Cl. 257/103

(57) ABSTRACT

The present invention enhances the light extraction from the topside of the LED by an appropriate choice of the spacing from the active region to the reflective ohmic contact. Proper selection of the spacing from the active region to the reflective contact causes the interference pattern of upwardly-directed light to concentrate light within the escape cone for emission. Appropriate spacings are shown to be approximately λₙ/4, and to lie in the ranges 2.3 λₙ/4≦d≦3.1 λₙ/4 (favorably ≈2.6 λₙ/4), and 4.0 λₙ/4≦d≦4.9 λₙ/4 (favorably ≈4.5 λₙ/4). Extraction of light is thereby enhanced.

### RELATED APPLICATIONS

The present application is a continuation-in-part of application Ser. No. 09/469,657, filed Dec. 22, 1999 and incorporated herein by reference, and claims priority therefrom pursuant to 35 U.S.C. § 120 as to common subject matter.

### BACKGROUND

1. Technical Field

The present invention relates to the general field of flipchip light emitting diodes and, more particularly, to improving the efficiency with which light is extracted from the topside of such devices.

2. Description of Related Art

Light emitting diodes (“LEDs”) are a highly durable solid state source of light capable of achieving high brightness and having numerous applications including displays, illuminators, indicators, printers, and optical disk readers among others. LEDs are fabricated in several geometric configurations, including a “flipchip” design having a reflective ohmic contact and a second ohmic contact on one side and a substrate transmissive to the LED's emitted light as the opposite side. Typically, the reflective ohmic contact is the positive contact (anode) and the other contact is the negative contact (cathode) since holes (positive charge carriers) have a smaller diffusion length in typical LED materials than do electrons (negative charge carriers). Thus, the less conductive p-layer needs to cover a large area of the LED. The long diffusion length of electrons makes it practical to inject electrons over a restricted surface area by means of a relatively small contact. The second ohmic contact is provided in a recess adjacent to the n-type layers so as not to interfere significantly with the light exiting from the LED.

The total amount of light emitted from the LED (i.e., the total integrated flux) is the integrated flux emitted from the topside (towards the substrate) of the device added to the integrated flux emitted from the sides of the device. Side-emitted light is typically guided to the sides of the device by a waveguide created by reflective surfaces and various device layers having different indices of refraction. Waveguided light typically undergoes several reflections on its path to the side of the device, losing intensity with each reflection. In addition, light passing through the active region may be absorbed. Thus it is advantageous to extract as much light as possible from the topside of the device in the first pass, tending thereby to reduce internal losses and increase the total integrated flux.

Flipchip LEDs have a “top escape cone” near the active region such that light beams impinging on the topside from within the LED and lying within the escape cone exit directly from the topside of the device. For economy of language, we refer to the top escape cone merely as the “escape cone,” understanding thereby that maximum topside light emission is a significant LED performance goal. The escape cone is determined by several device parameters including the indices of refraction of the various layers within the device. Light beams impinging on the topside and not within the escape cone undergo total internal reflection. Such internally reflected light typically exits from the side of the device or undergoes further internal reflections and loss of intensity within the device. Thus, one approach to increasing the intensity emerging from the topside of the LED is to increase the flux impinging on the topside that lies within the escape cone.

Some configurations of flipchip LEDs have the light-emitting active region located in close proximity to the reflective contact. In particular, interference patterns occur if the separation of the active region from the reflective contact is less than approximately 50% of the coherence length of the light emitted by the active region. In such cases, light from the active region propagating towards the topside of the LED interferes with light from the active region propagating from the LED following reflection by the reflective contact. These dual-path interference patterns cause spatial variations in the intensity of the light impinging on the topside from within the LED. In particular, such spatial variations can cause flux to shift to large impact angles, often lying outside of the escape cone. Such light outside the escape cone is lost to topside emission, hindering device efficiency. The present invention relates to placement of quantum wells at appropriate distances from the reflective contact so as to concentrate light within the escape cone, thereby increasing extraction efficiency and increasing the total integrated flux produced by the LED.

### SUMMARY

The present invention relates to a flipchip LED comprising a light emitting active region having a reflective ohmic contact separated from the active region by one or more layers. Light emitted from electron-hole recombinations occurring in the active region creates interference patterns with light reflected by the reflective contact. The structure of the interference patterns is determined by the structure and materials of the LED, including the spacing from the active region to the reflective contact. Different interference patterns cause different amounts of radiation to be directed towards the topside of the device within the escape cone for emission. Thus, different spacings lead to different amounts of radiation being emitted from the topside of the device and, hence, to different light extraction efficiencies.

The present invention enhances the light extraction from the topside of the LED by an appropriate choice of the spacing from the active region to the reflective ohmic contact. Proper selection of the spacing from the active region to the reflective contact causes the interference pattern of upwardly-directed light to concentrate light within the escape cone for topside emission. This interference pattern may not necessarily be single-lobed. It is shown that enhanced topside light extraction can result from multiple lobes of light intensity lying within the escape cone.

A typical example is presented for 515 nm (nanometer) light emitted by a single quantum well InGaN active region with a GaN base layer, a sapphire substrate and an encapsulating gel. Enhanced topside light extraction occurs for spacings from the active region to the reflective contact in the approximate ranges 0.5 λₙ/4≦d≦1.3λₙ/4 (favorably≈λₙ/4), or 2.3 λₙ/4≦d≦3.1λₙ/4 (favorably≈2.6 λₙ/4), or 4.0 λₙ/4≦d≦4.9λₙ/4 (favorably≈4.5 λₙ/4) where λₙ is the wavelength of the light in the base layer, or approximately 214.6 nm for the above example (with an index of refraction of GaN approximately 2.4 and λₙ=515 nm/2.4). We express symbolically “approximately equal to” as ≈, and “less than or approximately equal to” as ≦. Generalizations to optically non-uniform base layers are described. In such cases it is convenient to relate λₙ to the optical distance or, equivalently, describe the separation d in terms of optical distance. Further generalizations to active regions containing multiple quantum wells are also described.

### DESCRIPTION OF THE DRAWINGS

The drawings herein are not to scale.

FIG. 1: Cross-sectional schematic depiction of a typical flipchip LED structure including transparent substrate, GaN base layer, light-generating active region, layer adjacent to the reflective ohmic contact with thickness d, and reflective ohmic contact.

FIG. 2: Cross-sectional schematic depiction of a typical flipchip LED structure including encapsulating gel and depiction of topside light emission.

FIG. 3: Cross-sectional schematic depiction of a typical flipchip LED as in FIG. 2 including refraction of a typical beam of light, 8, emerging from the topside of the device. The index of refraction of the three layers is denoted by n₁, n₂, n₃ as depicted.

FIGS. 4A and 4B: Angular distribution of the flux of light emitted from the LED depicted in FIG. 1 for different distances, d, as given in the legends (in nanometers). Units of flux are arbitrary and total integrated flux is given in the legend. Data is given for λ=515 nm with GaN base layer (n₁=2.4), sapphire substrate (n₂=1.8) and gel encapsulating layer (n₃=1.5).

FIG. 5: Flux emitted from the topside of the LED as function of separation distance, d, (in nm) from the active region to the reflective contact.

FIG. 6: Cross-sectional, cut-away depiction of a typical LED including an embodiment of the present invention.

### DETAILED DESCRIPTION

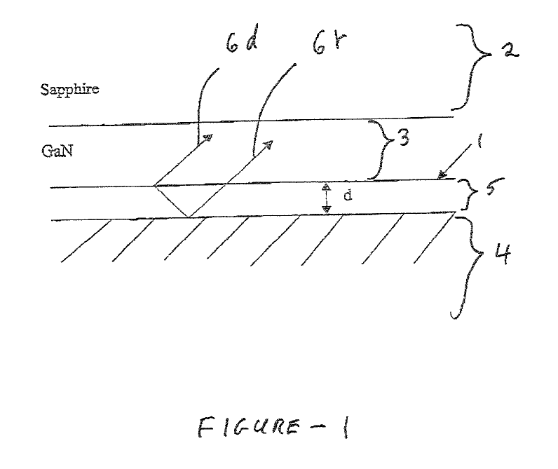

FIG. 1 depicts a portion of a typical flipchip LED comprising a light emitting active region 1 and a transparent substrate 2 separated by a base layer 3. The layers depicted in FIG. 1 are schematic only and not drawn to scale. We consider the illustrative example of an AlInGaN flipchip LED on a sapphire substrate with a GaN base layer as depicted in FIG. 1.

The present invention is not limited to the specific materials discussed in the illustrative examples. Numerous combinations of materials are employed in the fabrication of LEDs depending on the desired emission wavelength of the device, and other performance characteristics. Active regions can comprise AlInGaN, AlInGaP as well as other materials known in the art. Typical stoichiometries for AlInGaN and AlInGaP are AlₓIn_{y}Ga_{z}N and AlₓIn_{y}Ga_{z}P wherein x, y and z satisfy 0≦x≦1 and 0≦y≦1 and 0≦z≦1 and x+y+z=1.

Silicon carbide (SiC) and gallium phosphide (GaP) have also been used as transparent substrate materials analogous to the sapphire employed in the examples described herein. Base layers can include the GaN described herein as well as InAlP and other base layers known in the art. In general, the layers of a typical LED are not a single composition throughout but can be composed of numerous sublayers having different compositions and properties. However, the present invention is generally applicable to all such combinations of layers and sublayers, as it depends on the wavelength of the light emitted, on the spacings from light emitting regions to reflective regions and on the optical properties encountered by the light during its traverse through the LED, irrespective of the particular materials. The examples presented herein are for purposes of illustration and not limitation and are intended to be typical and representative of general LEDs.

A base layer 3, comprising a single layer of one or more constituent sublayers, is typically grown epitaxially on the substrate 2 as a transition region between the substrate and the light emitting active region 1. Typically, Metal-Organic Chemical Vapor Deposition (MOCVD) is used to grow one or more sublayers comprising the base layer, although other deposition techniques are known and used in the art. For the particular illustrative example of AlInGaN LED's described herein, the base layer is a III-nitride compound, typically including at least one layer of n-doped GaN.

The reflective positive ohmic contact 4 lies at a separation d from active region 1 and has one or more p-type layers 5 lying between the active region 1 and the contact 4. Layer 5 can comprise one layer or can comprise multiple sublayers having distinct compositions, doping characteristics and refractive indices from sublayer to sublayer or a gradation of compositions, electrical properties and optical properties throughout the thickness of layer 5. Layer 5 is not limited to p-type materials. N-type layers can be included as one or more sublayers in layers having overall p-type conductivity, and layers having overall n-type conductivity can also be used. For simplicity of depiction and discussion and not limiting the present invention, we consider a single layer 5 having p-type conductivity.

Light emitted from electron-hole recombinations occurring in the active region 1 can be directed into the transparent substrate directly, 6d, or following reflection from ohmic contact 4 such as those beams denoted by 6r. The coherence length (or pulse length) for light emitted in active region 1 is typically around 3 um (um=micrometer microns=10⁻⁶ meter) in GaN. Thus, if separation d is less than about 50% of the coherence length (d≦1.5 um in GaN), interference between direct (6d) and reflected (6r) beams is expected to occur.

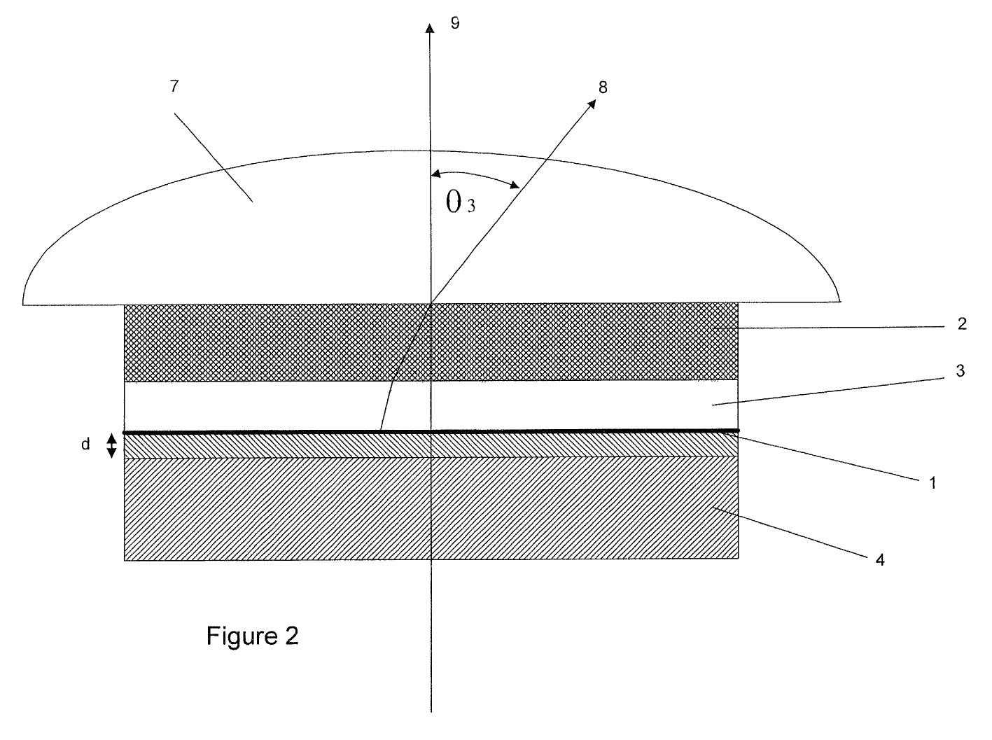

FIG. 2 depicts the LED structure of FIG. 1 and includes an encapsulating gel, 7, or other encapsulating layer. The encapsulating gel 7 may optionally be formed into a lens as depicted in FIG. 2.

Light originating in active region 1 may emerge from the LED via the topside, passing through encapsulating gel 7, or may be emitted through the side of the LED following a waveguided propagation toward the horizontal direction of FIG. 1 or FIG. 2. Side emission following waveguided propagation is typically subject to several internal reflections within the LED, including the possibility of several passes through the active region. As a result, side emitted light typically suffers higher attenuation than topside emitted light. Even if all top and side emitted light is collected and put to use as the output of the LED, it is advantageous that as much emission as feasible occur through the top surface. Thus, an important objective of the present invention is to increase the extraction of light from the LED by increasing the fraction of total light generated by the LED that is emitted from the topside, through the transparent substrate. A typical topside emitted light beam is depicted as 8 in FIG. 2. Beam 8 may emerge from the topside directly as depicted in FIG. 2 or following internal reflection within the LED from the reflective contact, depicted as beam 6r in FIG. 1.

To be concrete in our descriptions, we consider in detail the case of a GaN base layer having a substantially uniform index of refraction throughout. Generalizations to base layers having non-uniform indices of refraction (such as arising from multiple layers of different materials, gradations of optical properties, and the like) is straight-forward by the use of optical distances obtained by summing or integrating (physical thickness of layer i)/(index of refraction of layer i) over various layers of base layer material. Therefore, examples presented herein for GaN having a uniform index of refraction are illustrative and not limiting.

Light generated in active region 1 and emerging from the topside of the LED passes through base layer 3, substrate 2 and encapsulating gel 7 and undergoes refraction at each interface as depicted in FIG. 2. For the typical case depicted in FIG. 1, GaN base layer has an index of refraction n=2.4. Sapphire has n=1.8 and typical encapsulating gel has n=1.5. Thus, refraction away from the normal occurs as depicted in FIG. 2, causing the light to emerge from substrate 2 into encapsulating gel 7 with an angle from the normal of θ₃.

However, as light travels from the site of its formation into the encapsulating gel 7 through successive regions of lower index of refraction (3, 2 and 7), the possibility of total internal reflection arises at each interface. That is, if beam 8 strikes the 3-2 or 2-7 interface from the higher index side at too glancing an angle, no light will enter the lower index material comprising the (upper) adjacent region.

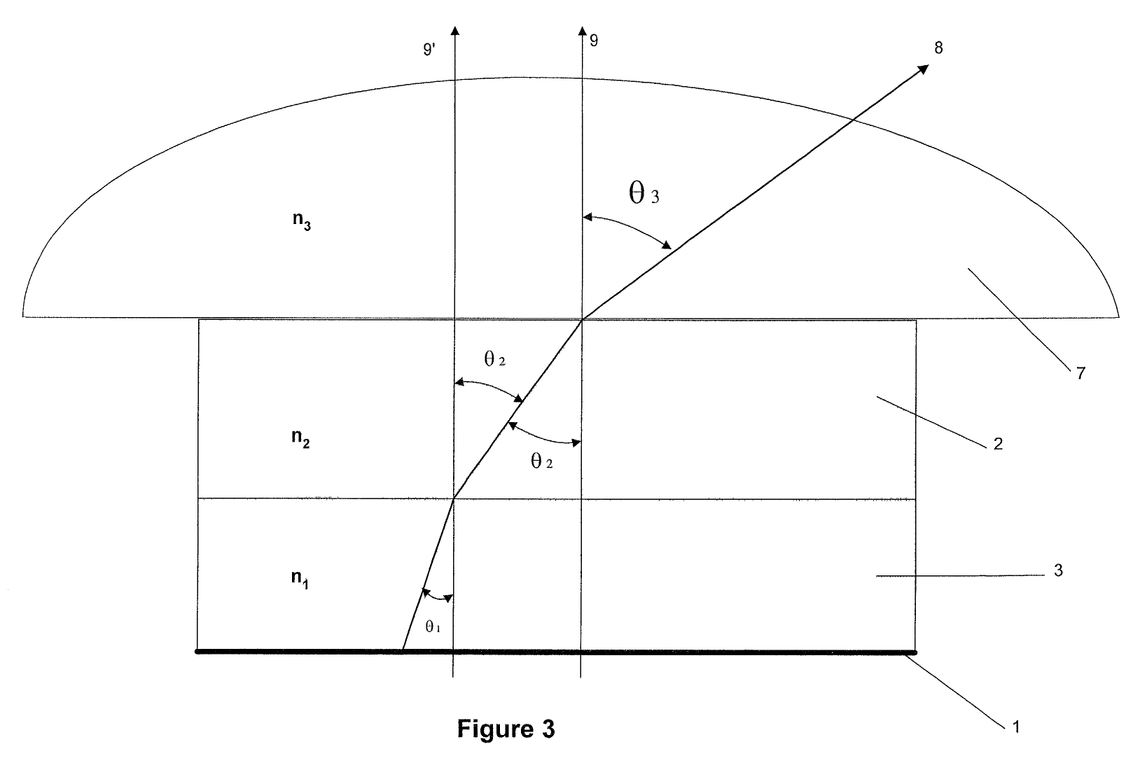

Applying Snell's Law to FIG. 3 gives

n₁ sin θ₁=n₂ sin θ₂=n₃ sin θ₃.

The escape cone is determined by θ₃=90°, or

sin θ₁ (escape)=(n₃/n₁).

Using the above values for the indices of refraction for GaN, sapphire and encapsulating gel yields θ₁(escape)≈38.7°. Thus, light striking the n₁-n₂ interface from the n₁ side will not emerge from the topside of the device if the angle of incidence exceeds θ₁(escape), about 38.7°.

Light totally internally reflected is redirected into the LED, undergoing additional internal reflections and the possibility of additional attenuation, perhaps to emerge as side-emitted light or to re-emerge from the topside. In either case, light totally internally reflected on its way to topside emission undergoes additional attenuation and causes a reduction in the overall light emission from the LED. Reducing the light undergoing total internal reflection (or equivalently, increasing the light entering the escape cone) increases the useful topside light emission of the LED. Thus, an important objective of the present invention is to arrange the spacing of the active region from the reflective surface so as to increase the fraction of emitted light lying within the escape cone.

Conditions occurring in typical LEDs lead to interference between light created in the active region and directly travelling in the direction of the LED topside (6d), and light traveling towards the topside following reflection (6r). Such interference affects the amount of light impinging on the topside of the LED within the escape cone and, therefore, affects the topside emission from the LED. Increasing this light intensity by management of the interference patterns is one objective of the present invention.

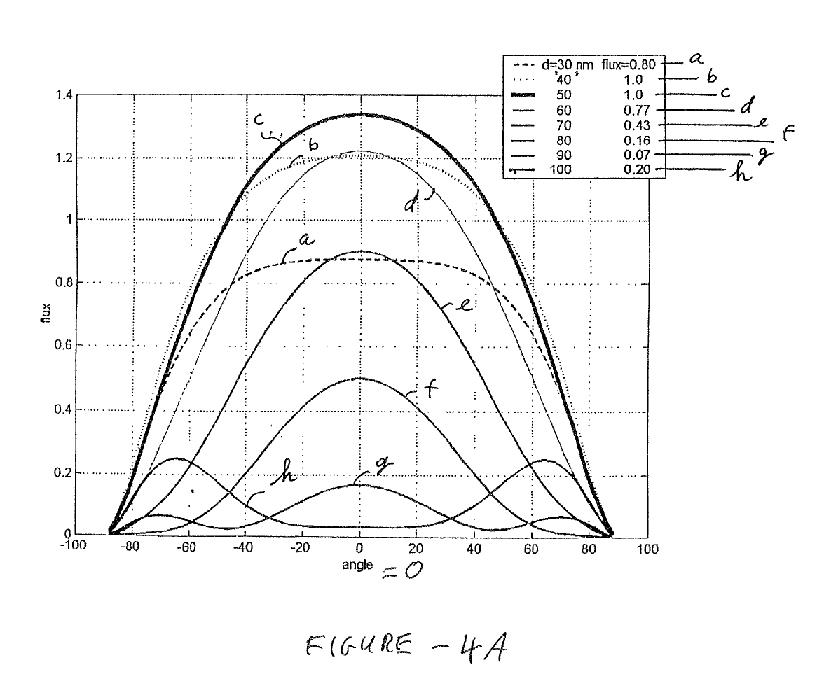

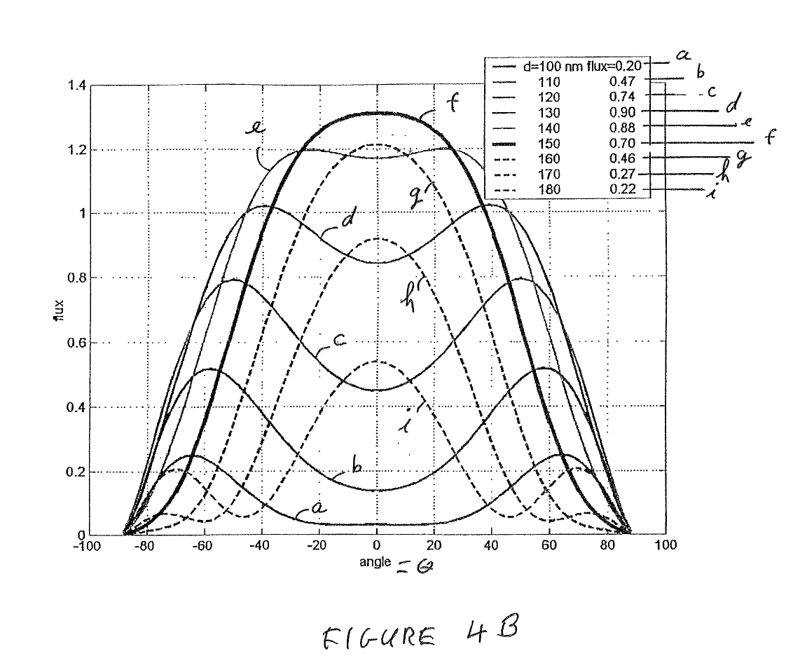

The total integrated flux emitted by the LED is the integrated flux emitted from the topside of the device added to the integrated flux emitted from the side edges of the device. The flux emitted from the topside of the device is depicted in FIGS. 4A and 4B. FIGS. 4A and 4B depict computer-generated examples of the far-field emitted light intensity (or flux) as a function of the direction of emission with respect to the normal to the LED, θ₃, defined in FIG. 2. Various values of d are depicted from curve “a” of FIG. 4A having d=30 nm to curve “i” of FIG. 4B having d=180 nm (nm=nanometer, 1 nm=10⁻⁹ meter=0.001 um). The units of flux are arbitrary as only the variations of flux with angle are of concern. The radiation patterns depend upon the distance, d, the wavelength of emitted light, the effective indices of refraction of the materials through which the light passes in exiting from the LED, among other factors. The radiation patterns clearly change as d changes, changing the flux lying within the escape cone of 38.7°.

FIGS. 4A and 4B also indicate the total integrated flux emerging from the topside of the LED for the various values of d. Topside flux is seen to vary by more than a factor of 10 from 0.07 at d=90 nm (FIG. 4A, curve g), to 1.0 at d=40, 50 nm (FIG. 4A, curves b and c). Thus, placement of the active region with respect to the reflective contact can have a major effect on the light extracted from the topside of the LED.

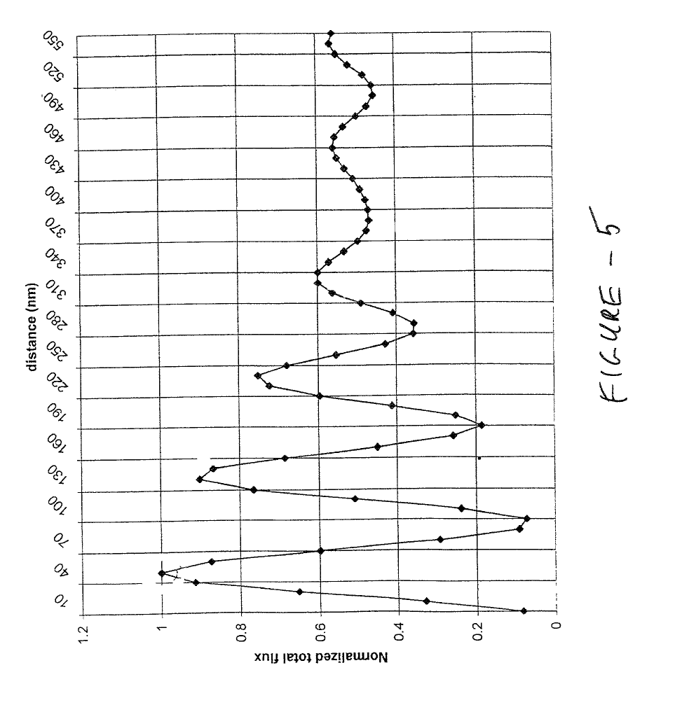

FIG. 5 presents computer-generated results for the light emitted from the topside of the LED device as a function of distance, d, from the active region to the reflective contact. Results in FIG. 5 are presented for a single quantum well device with an active region of GaN, a sapphire substrate and an encapsulating gel emitting a wavelength in vacuum of 515 nm. The indices of refraction for the GaN, sapphire and gel are taken to be 2.4, 1.8 and 1.5 respectively. The numerical results presented in FIG. 5 show that local maxima in the topside emitted light occurs at approximately the following values of d:

1) d≈λₙ/4 (0.5λₙ/4≦d≦1.3λₙ/4)

2) d≈2.6 λₙ/4 (2.3 λₙ/4≦d≦3.1 λₙ/4)

3) d≈4.5 λₙ/4 (4.0 λₙ/4≦d≦4.9 λₙ/4) Eq. 1

Eq. 1 is been determined for the particular example described above, that is a single quantum well structure emitting 515 nm light and having n₁=2.4, n₂=1.8 and n₃=1.5. The escape cone is determined by n₁ and n₃. The interference pattern is determined by λₙ. Thus, it is a straight forward calculation for any set of n₁, n₂, n₃ and λₙ to arrive at preferred distances analogous to Eq. 1 by extracting the numbers from a curve similar to that depicted in FIG. 5. Thus, the present invention permits management of the interference patterns for improved topside emission for any set of n₁, n₂, n₃ and λₙ. As noted above, the various layers of the device depicted in FIGS. 1-3 need not be composed of single materials with uniform properties throughout, but can consist of one or more sublayers having different optical properties. The set of n₁, n₂, n₃ denotes effective indices of refraction for each region encountered by the light, taking suitable averages of indices of refraction for various sublayers that may be present (if any) within each region. That is, n₁ is the effective index of refraction experienced by the light passing through region 3, not necessarily implying that region 3 has a constant index of refraction. Similar averages apply to other regions having possibly varying indices of refraction.

The maximum total emitted flux in FIG. 4B, 0.90, is obtained for curve “d” at a separation of 130 nm. It is clear from FIG. 4B that this maximum in total emitted flux occurs for a radiation pattern not peaked about the central perpendicular axis of the light emitting region. That is, spacing the reflective plane from the light emitting region such that flux intensity is directed primarily normal to the surface (0 deg. in FIG. 4B or “on-axis”) does not necessarily lead to maximum total emitted flux. Curve “f” in FIG. 4B provides marked on-axis peaking of emitted radiation, but at a considerable sacrifice in the total emitted flux (that is, 0.70 for “f” vs 0.90 for “d”). Thus, spacing the light emitting region from the reflector so as to improve on-axis light emission may be very suboptimal for obtaining maximal LED total brightness.

The data presented thus far relates to a single quantum well (SQW) active region emitting light at 515 nm. However, the present invention is not limited to SQW and can also be used in connection with multiple quantum well (MQW) active regions. For example, the center of brightness for MQWs can be located such that the distance from the center of brightness to the reflective surface satisfies Eq. 1 (as generalized for any set of n₁, n₂, n₃ and λₙ).

Alternatively (or additionally) MQWs may be present in clusters comprising one or more quantum wells in each cluster. For such cases, the center of brightness of each cluster can be selected to satisfy Eq. 1 (as generalized for any set of n₁, n₂, n₃ and λₙ).

It is known that the wavelength emitted by a quantum well can be varied by changing the composition and/or the fabrication conditions of the quantum well. Thus, different quantum wells of the same active region may be located such that the wavelengths and distances from the center of brightness of a particular cluster of quantum wells emitting wavelength λᵢ satisfy Eq. 1 (as generalized to any set of n₁, n₂, n₃ and λₙ).

### EXAMPLE

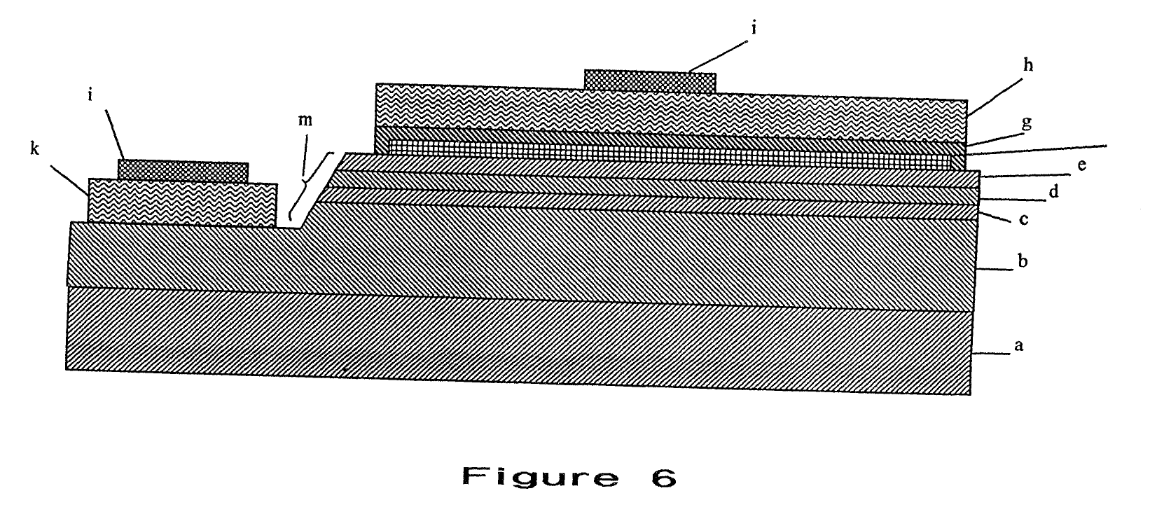

FIG. 6 depicts a cross-sectional schematic view (not to scale) of a typical LED in which one or more embodiments of the present invention can be used. This example is illustrative of a particular LED system favorably employing one or more embodiments of the present invention and is not to be construed to limit the scope of the present invention to a particular LED of family of LEDs as depicted or otherwise.

FIG. 6 depicts an embodiment utilizing a III-Nitride semiconductor system. Successive layers of GaInAlN are deposited are deposited on a sapphire substrate (a) in the following order: i) An n-type GaN layer (b). ii) A multiple quantum well active region (c) consisting in this example of four InGaN quantum wells separated by GaN barriers. iii) An AlGaN p-type barrier layer (c). iv) A p-type GaN contact layer (e). The optical distance from the final surface of the p-type GaN (that is, the plane of the e/f interface) to the center of the quantum wells (that is, the center of layer d), is chosen to be approximately 0.65λₙ. Although 0.65λₙ is advantageously employed in connection with this embodiment, other values of λₙ given by Eq. 1 (particularly 0.25λₙ and 1.125 λₙ) can also be used.

The following structures are formed by well-known evaporation and photolithographic techniques selected to be suitable for the structures to be fabricated and for the materials used: A reflective p-contact of silver (f). A protective layer comprising Ti (g) that surrounds the reflective contact (f) as depicted in FIG. 6. A mesa (m). An aluminum cap (h). An aluminum n-contact (k). Gold-based solder pads (i). The chip is inverted from the orientation depicted in FIG. 6 and soldered to a silicon submount. Light originating in active region (c) is extracted through the sapphire surface (a).

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

We claim:

1. A structure for a light emitting diode comprising:
a) a substantially planar light emitting region capable of emitting radiation and;
b) a reflector reflective of said radiation and separated from said light emitting region by a separation, wherein said separation is such that interferences between direct and reflected beams of said emitted radiation cause radiation to concentrate in the top escape cone of said light emitting diode.

2. A structure for a light emitting diode comprising:
a) a substantially planar light emitting region capable of emitting radiation of wavelength λₙ, and;
b) a reflector reflective of said radiation and separated from said light emitting region by a separation d wherein d lies in the range from approximately 0.5 λₙ/4 to approximately 1.3 λₙ/4, wherein λₙ, is the wavelength of said radiation emitted by said light emitting region within the region separating said light emitting region from said reflector.

3. A structure for a light emitting diode as in claim 2 wherein said separation d is approximately λₙ/4.

4. A structure for a light emitting diode comprising:
a) a substantially planar light emitting region capable of emitting radiation of wavelength λₙ, and;
b) a reflector reflective of said radiation and separated from said light emitting region by a separation d wherein d lies in the range from approximately 2.3 λₙ/4 to approximately 3.1 λₙ/4, wherein λₙ, is the wavelength of said radiation emitted by said light emitting region within the region separating said light emitting region from said reflector.

5. A structure as in claim 4 wherein said separation d is approximately 2.6 λₙ/4.

6. A structure for a light emitting diode comprising:
a) a substantially planar light emitting region capable of emitting radiation of wavelength λₙ, and;
b) a reflector reflective of said radiation and separated from said light emitting region by a separation d wherein d lies in the range from approximately 4.0 λₙ/4 to approximately 4.9 λₙ/4 wherein λₙ, is the wavelength of said radiation emitted by said light emitting region within the region separating said light emitting region from said reflective contact.

7. A structure as in claim 6 wherein said separation d is approximately 4.5 λₙ/4.

8. A structure as in claims 1-7 inclusive wherein said light emitting region comprises AlₓIn_{y}Ga_{z}N wherein x, y and z satisfy 0≦x≦1 and 0≦y≦1 and 0≦z≦1 and x+y+z=1.

9. A structure as in claims 1-7 inclusive wherein said light emitting region comprises multiple quantum wells.

10. A structure as in claim 9 wherein said distance d is from the center of brightness of said multiple quantum wells to said reflector.

11. A method of extracting light from the topside of a light emitting diode comprising:
a) providing a substantially planar light emitting region capable of emitting radiation of wavelength λₙ, and;
b) providing a reflector reflective of said radiation and separated from said light emitting region by a separation d wherein d lies in the range from approximately 0.5λₙ/4 to approximately 1.3λₙ/4, wherein λₙ, is the wavelength of said radiation emitted by said light emitting region within the region separating said light emitting region from said reflector.

12. A method as in claim 11 wherein said d is approximately λₙ/4.

13. A method of extracting light from the topside of a light emitting diode comprising:
a) providing a substantially planar light emitting region capable of emitting radiation of wavelength λₙ, and;
b) providing a reflector reflective of said radiation and separated from said light emitting region by a separation d wherein d lies in the range from approximately 2.3 λₙ/4 to approximately 3.1 λₙ/4, wherein λₙ, is the wavelength of said radiation emitted by said light emitting region within the region separating said light emitting region from said reflector.

14. A method as in claim 13 wherein said separation d is approximately 2.6 λₙ/4.

15. A method of extracting light from the topside of a light emitting diode comprising:
a) providing a substantially planar light emitting region capable of emitting radiation of wavelength λₙ, and;
b) providing a reflector reflective of said radiation and separated from said light emitting region by a separation d wherein d lies in the range from approximately 4.0 λₙ/4 to approximately 4.9 λₙ/4 wherein λₙ, is the wavelength of said radiation emitted by said light emitting region within the region separating said light emitting region from said reflector.

16. A method as in claim 15 wherein said separation d is approximately 4.5 λₙ/4.

17. A method as in claims 11-16 inclusive, wherein said light emitting region comprises AlₓIn_{y}Ga_{z}N wherein x, y and z satisfy 0≦x≦1 and 0≦y≦1 and 0≦z≦1 and x+y+z=1.

18. A method as in claims 11-16 inclusive wherein said light emitting region comprises multiple quantum wells.

19. A method as in claim 18 wherein said distance d is from the center of brightness of said multiple quantum wells to said reflector.

20. A far-field pattern of light intensity emitted from a light emitting diode as an article of manufacture, said pattern produced according to the methods of claims 11-16 inclusive.

21. A far-field pattern of light intensity emitted from a light emitting diode as an article of manufacture, said pattern produced according to the methods of claim 17.

22. A far-field pattern of light intensity emitted from a light emitting diode as an article of manufacture, said pattern produced according to the methods of claim 18.

23. A far-field pattern of light intensity emitted from a light emitting diode as an article of manufacture, said pattern produced according to the methods of claim 19.

24. A light emitting diode comprising:
a) a sapphire substrate having a substantially planar face; and,
b) an n-type GaN layer on said substantially planar face of said sapphire substrate; and,
c) a multiple quantum well active region on said n-type GaN layer; and,
d) an AlGaN p-type barrier layer on said active region; and,
e) a p-type GaN contact layer on said barrier layer; and,
f) a reflective p-contact on said contact layer and having a substantially planar interface therewith; and,
g) a protective layer surrounding said reflective p-contact; and,
h) an aluminum cap on said protective layer; and,
i) an n-contact on said n-type GaN layer; and,
j) at least one first solder pad on said aluminum cap and at least one second solder pad on said n-contact;
wherein the optical distance from the center of said active region to said interface is approximately 0.65 λₙ wherein λₙ is the wavelength of the light emitted by said active region within the region separating said active region from said interface.

25. A light emitting diode as in claim 27 wherein said multiple quantum well active region comprises four InGaN quantum wells separated by GaN barrier layers.

26. A light emitting diode comprising:
a) a sapphire substrate having a substantially planar face; and,
b) an n-type GaN layer on said substantially planar face of said sapphire substrate; and,
c) a multiple quantum well active region on said n-type GaN layer; and,
d) an AlGaN p-type barrier layer on said active region; and,
e) a p-type GaN contact layer on said barrier layer; and,
f) a reflective p-contact on said contact layer and having a substantially planar interface therewith; and,
g) a protective layer surrounding said reflective p-contact; and,
h) an aluminum cap on said protective layer; and,
i) an n-contact on said n-type GaN layer; and,
j) at least one first solder pad on said aluminum cap and at least one second solder pad on said n-contact;
wherein the optical distance from the center of said active region to said interface is approximately 1.125 λₙ wherein λₙ is the wavelength of the light emitted by said active region within the region separating said active region from said interface.

27. A light emitting diode as in claim 26 wherein said multiple quantum well active region comprises four InGaN quantum wells separated by GaN barrier layers.

28. A light emitting diode comprising:
a) a sapphire substrate having a substantially planar face; and,
b) an n-type GaN layer on said substantially planar face of said sapphire substrate; and,
c) a multiple quantum well active region on said n-type GaN layer; and,
d) an AlGaN p-type barrier layer on said active region; and,
e) a p-type GaN contact layer on said barrier layer; and,
f) a reflective p-contact on said contact layer and having a substantially planar interface therewith; and,
g) a protective layer surrounding said reflective p-contact; and,
h) an aluminum cap on said protective layer; and,
i) an n-contact on said n-type GaN layer; and,
j) at least one first solder pad on said aluminum cap and at least one second solder pad on said n-contact;
wherein the optical distance from the center of said active region to said interface is approximately 0.25 λₙ wherein λₙ is the wavelength of the light emitted by said active region within the region separating said active region from said interface.

29. A light emitting diode as in claim 28 wherein said multiple quantum well active region comprises four InGaN quantum wells separated by GaN barrier layers.

30. A structure for a light emitting diode comprising:
a) a substantially planar light emitting region capable of emitting radiation and;
b) a reflector reflective of said radiation and separated from said light emitting region by a separation, wherein said separation is such that interferences between direct and reflected beams of said emitted radiation cause radiation to concentrate in the top escape cone of said light emitting diode but not on the central perpendicular axis of said light emitting region.
